(19) United States
(12) Patent Application Publication
(10) Pub. No.: US 2008/0178058 A1
(43) Pub. Date: Jul. 24, 2008

(54) Decoding apparatus and method

(75) Inventors: Shieh-Hsing Kuo, Hsinchu (TW); Chien-Chih Chen, Hsinchu (TW)

Correspondence Address: GALLAGHER & LATHROP, A PROFESSIONAL CORPORATION, 601 CALIFORNIA ST, SUITE 1111, SAN FRANCISCO, CA, 94108, US

(73) Assignee: Realtek Semiconductor Corp., Hsinchu (TW)

(21) Appl. No.: 12/009,413

(22) Filed: Jan. 17, 2008

(30) Foreign Application Priority Data
Jan. 19, 2007 (TW) 096102087

(51) Int. Cl. H03M 13/00

(52) U.S. Cl. 714/755

(57) ABSTRACT

A decoding apparatus includes a decoding unit and an updated erasure data generating unit. The decoding unit receives read data and updated erasure data, and generates decoding data including flag information according to the read data and the updated erasure data. The updated erasure data generating unit is coupled to the decoding unit, receives the flag information and original erasure data, and generates the updated erasure data according to the flag information and the original erasure data. The original erasure data is generated by a reading device that reads a storage medium. A decoding method performed by the decoding apparatus is also disclosed.

### CROSS-REFERENCE TO RELATED APPLICATION

This application claims priority of Taiwanese application no. 096102087, filed on Jan. 19, 2007.

### BACKGROUND OF THE INVENTION

1. Field of the Invention

The invention relates to a decoding apparatus and method, more particularly to a product code decoding apparatus and method.

2. Description of the Related Art

Referring to FIG. 1, in a digital versatile disc (DVD), error-correction decoding of stored data is conducted in units of data blocks 1. Each data block 1 has a size of 182×208 bytes, and includes sixteen data sectors 11, a parity of outer code (PO) region 12 and a parity of inner code (PI) region 13. Each data sector 11 has a size of 172×12 bytes, and includes a 4-byte error detection code (EDC) for detecting integrity of the data sector 11. The PO region 12 has a size of 172×16 bytes, and the PI region 13 has a size of 10×208 bytes. The parity of outer code and parity of inner code are generated through Reed-Solomon Product Code (RSPC) encoding of columns and rows of the data sectors 11, and are used to correct errors in the data block 1.

When a conventional decoding apparatus conducts error-correction decoding using the parity of outer code and the parity of inner code, positions which are unable to be correctly decoded are first marked as erasures, and for each row and each column, it is determined whether erasure decoding or pure error decoding is to be conducted according to the number of erasures. Erasure decoding can increase error correction capability (without erasure decoding, each column can have 8 bytes corrected and each row can have 5 bytes corrected; with erasure decoding, each column can have 16 bytes corrected and each row can have 10 bytes corrected) to result in better decoding capacity. Nevertheless, when the number of erasures is larger than the number of errors that can be corrected using erasure decoding, only pure error decoding can be used for error correction, which often arises in erroneous results, and which reduces the decoding capacity significantly. Therefore, to improve decoding capacity, the probability of conducting erasure decoding must be increased accordingly. As such, how to mark erasures correctly and to use erasures for enhancing the ability to perform correct decoding are important to the industry.

In the conventional decoding apparatus, columns and rows are marked entirely as erasures when they are unable to be correctly decoded. When conducting PO error-correction decoding in rows, the number of erasures is the same as that of rows that are unable to be correctly decoded. In the same token, when conducting PI error-correction decoding in columns, the number of erasures is the same as that of columns that are unable to be correctly decoded. In practice, for those rows and columns that are unable to be correctly decoded, the entire data thereof are usually not erroneous. As a result, marking of an entire row or column that is unable to be correctly decoded as an erasure in the conventional method inevitably generates a greater number of erasures. Moreover, when there exists a burst error in a DVD, the numbers of rows and columns that are unable to be correctly decoded are most likely to be higher than the number of errors that can be corrected by erasure decoding, such that erasure decoding cannot be conducted in the conventional method and such that decoding capacity by the conventional decoding apparatus is significantly reduced.

### SUMMARY OF THE INVENTION

Therefore, an object of the present invention is to provide a decoding apparatus and method that can enhance decoding capacity and make efficient use of erasures.

According to one aspect of the present invention, there is provided a decoding apparatus that comprises a decoding unit and an updated erasure data generating unit. The decoding unit receives read data and updated erasure data, and generates decoding data including flag information according to the read data and the updated erasure data. The updated erasure data generating unit is coupled to the decoding unit, receives the flag information and original erasure data, and generates the updated erasure data according to the flag information and the original erasure data. The original erasure data is generated by a reading device that reads a storage medium.

According to another aspect of the present invention, there is provided a decoding method adapted for a data block read from a storage medium. The data block includes a plurality of data sectors, a parity of outer code region and a parity of inner code region. The decoding method comprises the steps of:

generating updated erasure data according to flag information and original erasure data, the flag information including a plurality of column flags and a plurality of row flags, each of the column flags and the row flags indicating decoding integrity of a respective one of columns and rows of the data block, the original erasure data being generated when the storage medium is being read and indicating known error positions in the data block; and

conducting error-correction decoding of the data block using the updated erasure data and a parity of outer code and a parity of inner code in the data block, and updating the flag information.

According to yet another aspect of the present invention, there is provided a decoding method comprising the steps of: generating decoding data including flag information according to read data and updated erasure data; and generating the updated erasure data according to the flag information and original erasure data.

### BRIEF DESCRIPTION OF THE DRAWINGS

Other features and advantages of the present invention will become apparent in the following detailed description of the embodiments with reference to the accompanying drawings, of which:

FIG. 1 is a schematic diagram to illustrate a data block in a digital versatile disc;

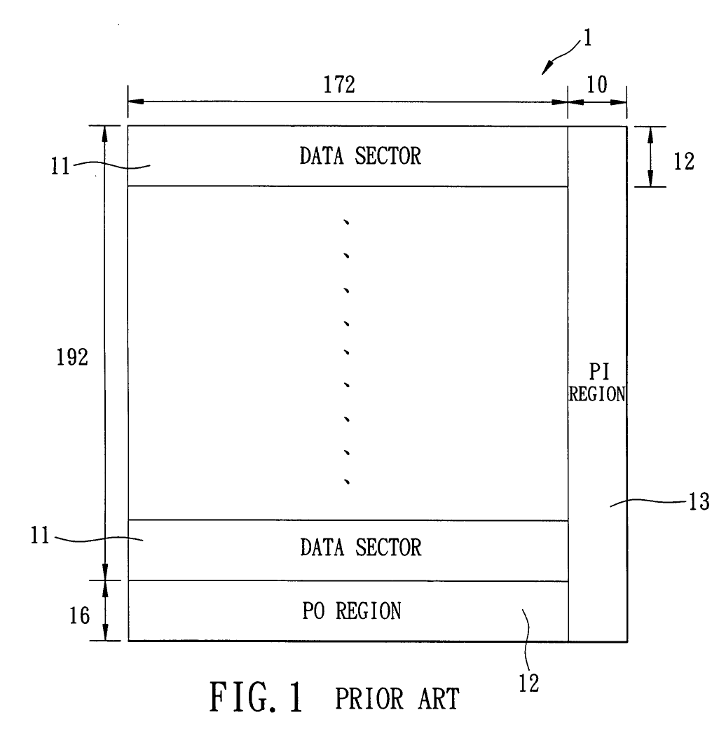

FIG. 2 is a block diagram of the first embodiment of a decoding apparatus according to the present invention;

FIG. 3 is a block diagram of the second embodiment of a decoding apparatus according to the present invention;

FIG. 4 is a schematic diagram to illustrate a difference in how erasures are marked between a conventional decoding apparatus and the present invention; and

FIG. 5 is a block diagram of the third embodiment of a decoding apparatus according to the present invention.

### DETAILED DESCRIPTION OF THE EMBODIMENTS

Before the present invention is described in greater detail with reference to the accompanying embodiments, it should be noted herein that like elements are denoted by the same reference numerals throughout the disclosure.

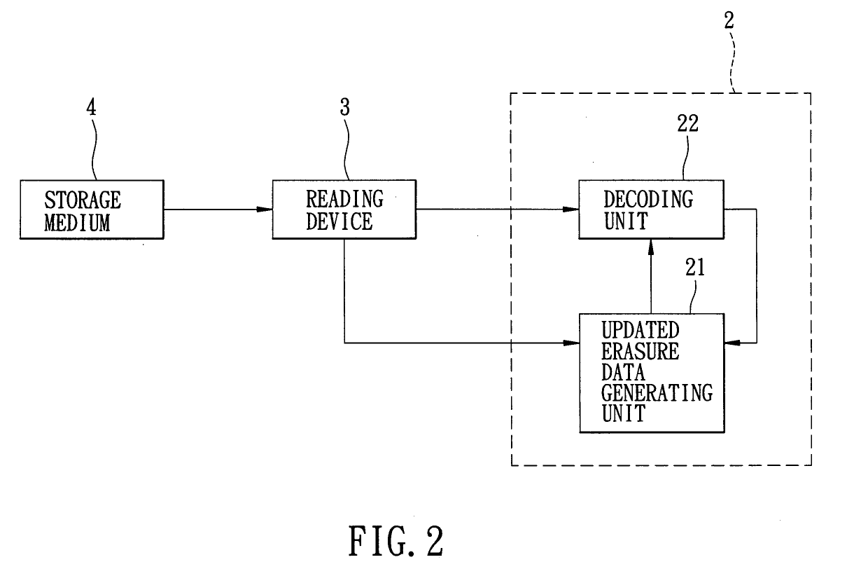

Referring to FIG. 2, the first embodiment of a decoding apparatus 2 according to the present invention is shown to be coupled electrically to a reading device 3, and includes an updated erasure data generating unit 21 and a decoding unit 22. The reading device 3 is for reading read data from a storage medium 4, and generates original erasure data to indicate known error positions in the read data during a process of reading. A method that may be employed by the reading device 3 to generate the original erasure data is disclosed in U.S. Patent Application Publication Number 2006/008255, the entire disclosure of which is incorporated herein by reference.

In this embodiment, the storage medium 4 is exemplified as a DVD but should not be limited thereto. The read data includes a data block. The data block includes sixteen data sectors, a parity of outer code region, and a parity of inner code region. Each data sector includes an error detection code. This invention is also adapted for other types of storage media, and the storage medium 4 is not restricted to current DVD data formats so as to suit diverse characteristics of erasure data in different types of storage media. That is, this invention is applicable to any apparatus that utilizes erasure decoding.

In this embodiment, the reading device 3 marks erasures in units of one byte, but can also mark erasures in units of several bytes. In other words, the present invention is not limited in this aspect.

The updated erasure data generating unit 21 receives flag information and the original erasure data generated by the reading device 3, and combines the flag information and the original erasure data to generate updated erasure data on the fly. The flag information includes a plurality of column flags, a plurality of row flags, and a plurality of sector flags. The column and row flags are used to indicate decoding integrity of a respective one of columns and rows of the data block. The sector flags are used to indicate whether a respective one of the data sectors has passed error detection.

The decoding unit 22, which is coupled to the updated erasure data generating unit 21, utilizes the updated erasure data generated by the updated erasure data generating unit 21 and the parity of outer code and parity of inner code in the data block for conducting error-correction decoding on the data block. The decoding unit 22 further updates the column flags and the row flags, utilizes the error detection codes in the data block to detect integrity of the data sectors, and updates the sector flags according to result of detection. Since error-correction decoding using the parity of outer code and the parity of inner code, and determination as to whether erasure decoding or pure error decoding is to be conducted according to the number of erasures for each row and each column are performed by the decoding unit 22 in a conventional manner, further details of the same are omitted herein for the sake of brevity.

In this embodiment, the updated erasure data generating unit 21 generates the updated erasure data by combining the flag information and the original erasure data on the fly. However, in other embodiments of this invention, the updated erasure data generating unit 21 may be configured so as to generate the updated erasure data by combining the flag information and the original erasure data not on the fly, which will be illustrated in the following second and third embodiments of the invention.

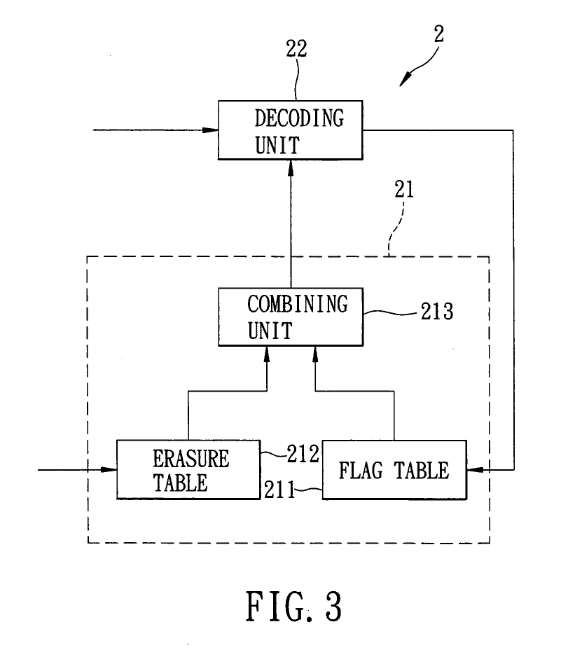

Referring to FIG. 3, the second embodiment of the decoding apparatus 2 of the present invention is shown to have an updated erasure data generating unit 21 including a flag table 211 for storing the flag information, an erasure table 212 for storing the original erasure data, and a combining unit 213 that is coupled to the flag table 211 and the erasure table 212 and that combines the flag information in the flag table 211 and the original erasure data in the erasure table 212 to generate the updated erasure data.

In this embodiment, the combining unit 213 generates the updated erasure data according to a polynomial function f(x, y), where x stands for the original erasure data, and y stands for the flag information. In one embodiment of the present invention, the combining unit 213 is a logic circuit. With reference to the original erasure data in the erasure table 212 and the flag information in the flag table 211, the combining unit 213 removes corresponding erasures in the original erasure data that were correctly decoded in a respective column or row and that have passed error detection in the respective data sector (which indicates that previous erasure marking is incorrect), and preserves the other erasures in the original erasure data for generating the updated erasure data. This can be represented by the function f(x,y)=x·y, in which the logic circuit used is an AND gate.

It should be noted that generation of the updated erasure data by the combining unit 213 is not limited to the above scheme where incorrect portions of the original erasure data are modified and correct portions of the original erasure data are preserved. In another embodiment, the original erasure data is preserved, and the columns, rows and data sectors that are unable to be correctly decoded are marked as erasures so as to generate the updated erasure data. This can be represented by the function f(x,y)=x+y, in which the logic circuit used is an OR gate. In still another embodiment, one of the original erasure data, and the columns, rows and data sectors that are unable to be correctly decoded is selected for erasure marking so as to generate the updated erasure data. This can be represented by the function f(x,y)=x or the function f(x,y)=y, in which the updated erasure data is generated according to one of the original erasure data and the flag information. In yet another embodiment, an option not to update can be selected based on actual operating conditions. Other schemes that can achieve the same purpose of updating belong to the scope of the present invention.

Moreover, in a further embodiment, the decoding unit 22 can provide feedback (not shown) to the combining unit 213 so as to adjust dynamically generation of the updated erasure data. That is, according to information generated during a process of decoding by the decoding unit 22, the combining unit 213 is able to adjust dynamically generation of the updated erasure data. For instance, when many columns, rows and data sectors are unable to be decoded correctly, the function f(x,y)=x·y is used; and when few columns, rows and data sectors are unable to be decoded correctly, the function f(x,y)=x+y is used.

It is noted that, unlike the prior art where entire columns and rows unable to be correctly decoded are marked as erasures, i.e., f(x, y)=y, when the combining unit 213 generates the updated erasure data using the function f(x, y)=x·y in this embodiment, the positions intersected by the original erasure data x and the flag information y are marked as erasures.

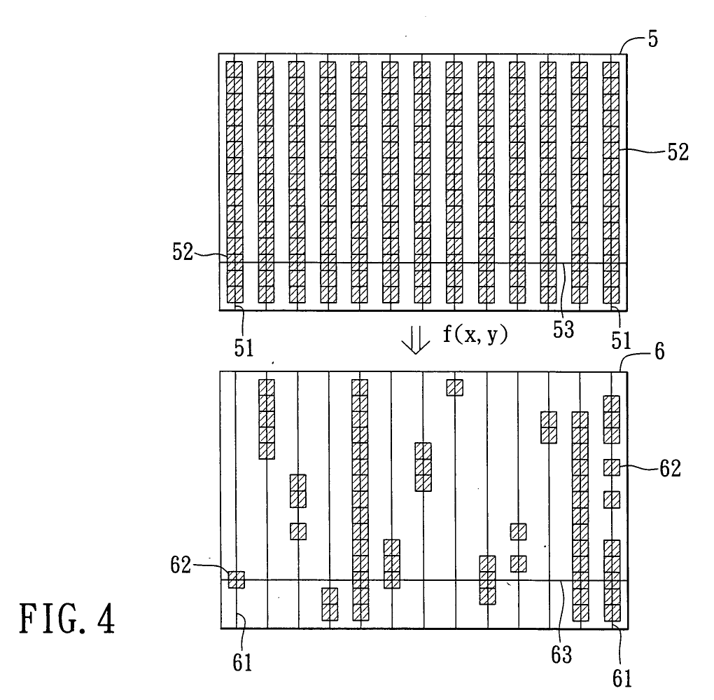

A simple example will now be illustrated with reference to FIG. 4. Assume that a data block having thirteen columns is unable to be correctly decoded. In the prior art, the thirteen columns are marked as erasures in their entirety. For data block 5, columns 51 are unable to be decoded correctly, and blocks 52 are marked as erasures. In this embodiment, when the function f(x,y)=x·y is used, only the positions (the known error positions) intersected by the thirteen columns and the original erasure data are marked as erasures. For data block 6, columns 61 are unable to be decoded correctly, and blocks 62 are marked as erasures. For this embodiment, since the number of erasures in row 63 is six, which is smaller than the maximum number of errors (i.e., 10 bytes) that can be corrected by erasure decoding, erasure decoding can be conducted for the row 63. In contrast, for the prior art, since the number of erasures in row 53 is thirteen, which is larger than the maximum number of errors that can be corrected by erasure decoding, erasure decoding cannot be conducted for the row 53.

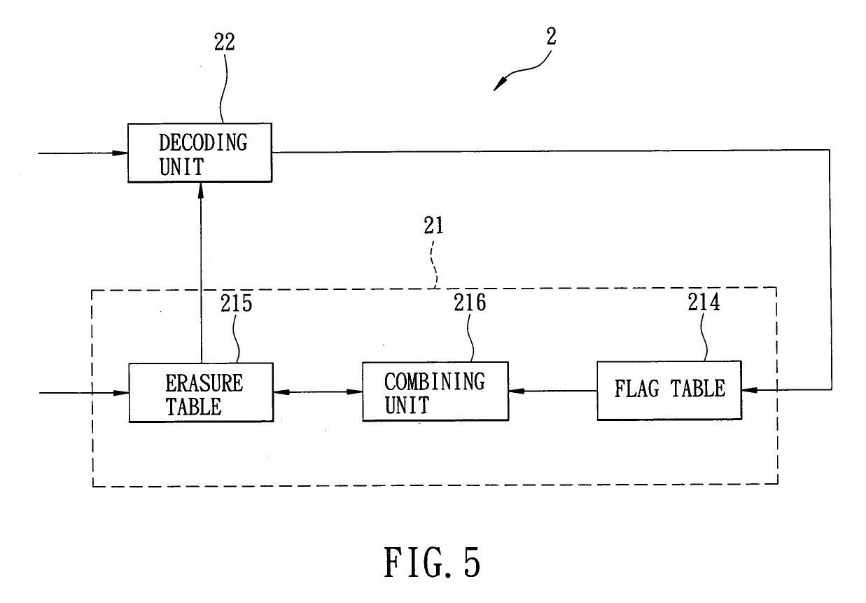

Referring to FIG. 5, the third embodiment of the decoding apparatus 2 of the present invention differs from the second embodiment in that: the updated erasure data generating unit 21 combines the flag information and first updated erasure data to generate second updated erasure data, and overwrites the first updated erasure data by the second updated erasure data.

In one implementation of the third embodiment, the updated erasure data generating unit 21 includes a flag table 214 for storing the flag information, an erasure table 215 for storing the updated erasure data, and a combining unit 216 that is coupled to the flag table 214 and the erasure table 215, and that combines the flag information in the flag table 214 and the erasure data in the erasure table 215 to generate new erasure data and that overwrites the erasure table 215. Source data of the updated erasure data is the original erasure data. It is noted that the connections among the components shown in FIG. 5 are only illustrative, and the scope of the present invention is not limited in this aspect. Other connections that can achieve the same purpose are considered to belong to the scope of this invention.

Since generation of the updated erasure data by the combining unit 216 is the same as that in the second embodiment, further details of the same will be omitted herein.

In sum, since the original erasure data is generated when the storage medium 4 is read and is combined with the flag information to generate the erasure data used by the decoding unit 22, the number of erasures can be reduced compared to the prior art so that this invention has a higher probability to conduct erasure decoding to thereby increase decoding capacity and efficiently use erasures.

It should be noted that the scope of the present invention is not limited to the above-mentioned embodiments. For example, in the first embodiment in FIG. 2, the decoding apparatus can further include a table (not shown), and the decoding unit 22 receives the updated erasure data generated by the updated erasure data generating unit 21 from the table. The table herein can be configured in the updated erasure data generating unit 21 or coupled between the updated erasure data generating unit 21 and the decoding unit 22. The scope of the present invention is not limited to these configurations.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A decoding apparatus comprising:
a decoding unit for receiving read data and updated erasure data, and for generating decoding data including flag information according to the read data and the updated erasure data; and
an updated erasure data generating unit for receiving the flag information and original erasure data, and generating the updated erasure data according to the flag information and the original erasure data, the original erasure data being generated by a reading device that reads a storage medium.

2. The decoding apparatus as claimed in claim 1, wherein said updated erasure data generating unit generates the updated erasure data by combining the flag information and the original erasure data on the fly.

3. The decoding apparatus as claimed in claim 1, wherein said updated erasure data generating unit combines the flag information and first updated erasure data to generate second updated erasure data, and overwrites the first updated erasure data by the second updated erasure data.

4. The decoding apparatus as claimed in claim 1, wherein the read data includes a data block, said decoding unit performing error-correction decoding on the data block according to the updated erasure data to generate the decoding data.

5. The decoding apparatus as claimed in claim 1, wherein the read data includes a plurality of data sectors, a parity of outer code region, and a parity of inner code region,
each of the data sectors including an error detection code,
the flag information including a plurality of sector flags, each of the sector flags indicating whether a respective one of the data sectors has passed error detection.

6. The decoding apparatus as claimed in claim 5, wherein said decoding unit utilizes the error detection codes of the data sectors to detect integrity of the data sectors, and updates the sector flags according to result of detection.

7. The decoding apparatus as claimed in claim 1, wherein said updated erasure data generating unit adjusts dynamically generation of the updated erasure data according to information generated during generation of the decoding data by said decoding unit.

8. The decoding apparatus as claimed in claim 1, wherein said updated erasure data generating unit comprises a flag table for storing the flag information, an erasure table for storing the original erasure data, and a combining unit coupled to said flag table and said erasure table, said combining unit combining the flag information in said flag table and the original erasure data in said erasure table to generate the updated erasure data.

9. The decoding apparatus as claimed in claim 8, wherein said combining unit is a logic circuit.

10. The decoding apparatus as claimed in claim 8, wherein said combining unit overwrites the original erasure data stored in said erasure table by the updated erasure data generated thereby, source data of the updated erasure data being the original erasure data.

11. The decoding apparatus as claimed in claim 1, wherein said decoding unit receives the updated erasure data generated by said updated erasure data generating unit from a table.

12. A decoding method adapted for a data block read from a storage medium, the data block including a plurality of data sectors, a parity of outer code region and a parity of inner code region, said decoding method comprising the steps of:
generating updated erasure data according to flag information and original erasure data, the flag information including a plurality of column flags and a plurality of row flags, each of the column flags and the row flags indicating decoding integrity of a respective one of columns and rows of the data block, the original erasure data being generated when the storage medium is being read and indicating known error positions in the data block; and
conducting error-correction decoding of the data block using the updated erasure data and a parity of outer code and a parity of inner code in the data block, and updating the flag information.

13. The decoding method as claimed in claim 12, wherein the updated erasure data is generated by combining the flag information and the original erasure data on the fly.

14. The decoding method as claimed in claim 12, wherein the flag information is combined with first updated erasure data to generate second updated erasure data, and the first updated erasure data is overwritten by the second updated erasure data.

15. The decoding method as claimed in claim 12, wherein generation of the updated erasure data is adjusted dynamically according to information generated during a process of decoding.

16. The decoding method as claimed in claim 12, each of the data sectors including an error detection code, wherein the flag information further includes a plurality of sector flags, each of the sector flags indicating whether a respective one of the data sectors has passed error detection,
the error detection codes of the data sectors being utilized to detect integrity of the data sectors during a process of decoding, and the sector flags being updated according to result of detection.

17. A decoding method comprising the steps of:
generating decoding data including flag information according to read data and updated erasure data; and
generating the updated erasure data according to the flag information and original erasure data.

18. The decoding method as claimed in claim 17, wherein the original erasure data is generated when a storage medium is read.

19. The decoding method as claimed in claim 17, wherein the updated erasure data is generated by combining the flag information and the original erasure data on the fly.

20. The decoding method as claimed in claim 17, wherein the flag information is combined with first updated erasure data to generate second updated erasure data, and the first updated erasure data is overwritten by the second updated erasure data.

21. The decoding method as claimed in claim 17, wherein the read data is generated through Reed-Solomon Product Code encoding.

22. The decoding method as claimed in claim 17, wherein the read data includes a data block that has a plurality of data sectors, a parity of outer code region and a parity of inner code region.

23. The decoding method as claimed in claim 22, wherein the decoding data is generated by conducting error-correction decoding on the data block according to the updated erasure data.

24. The decoding method as claimed in claim 23, wherein each of the data sectors includes an error detection code, the flag information including a plurality of sector flags, each of the sector flags indicating whether a respective one of the data sectors has passed error detection,
the error detection codes of the data sectors being utilized to detect integrity of the data sectors when generating the decoding data, and the sector flags being updated according to result of detection.

25. The decoding method as claimed in claim 17, wherein generation of the updated erasure data is adjusted dynamically according to information generated during generation of the decoding data.
